(19) United States
(12) Patent Application Publication
(10) Pub. No.: US 2010/0282166 A1
(43) Pub. Date: Nov. 11, 2010

(54) HEAT TREATMENT APPARATUS AND METHOD OF HEAT TREATMENT

(75) Inventors: Masanao FUKUDA, Toyama-shi (JP); Akihiro SATO, Toyama-shi (JP); Akinori TANAKA, Toyama-Shi (JP); Kazuhiro MORIMITSU, Toyama-shi (JP)

Correspondence Address: BRUNDIDGE & STANGER, P.C., 2318 MILL ROAD, SUITE 1020, ALEXANDRIA, VA, 22314, US

(73) Assignee: HITACHI-KOKUSAI ELECTRIC INC., Tokyo (JP)

(21) Appl. No.: 12/774,141

(22) Filed: May 5, 2010

(30) Foreign Application Priority Data
May 11, 2009 (JP) 2009-114801
Apr. 1, 2010 (JP) 2010-085197

(51) Int. Cl. C23C 16/32

(52) U.S. Cl. 118/722

(57) ABSTRACT

Provided is a heat treatment apparatus. The heat treatment apparatus comprises a process chamber configured to grow silicon carbide (SiC) epitaxial films on SiC substrates, a substrate holding tool configured to hold a plurality of substrates in a state where the substrates are vertically arranged and approximately horizontally oriented, so as to hold the substrates in the process chamber, a first reaction gas supply nozzle configured to supply a carbon-containing gas into the process chamber, a second reaction gas supply nozzle configured to supply a silicon-containing gas into the process chamber, a magnetic field generating coil disposed at an outside of the process chamber for electromagnetic induction heating, and a coil supporter configured to support the magnetic field generating coil. An upper end of the second reaction gas supply nozzle is lower than a lower end of the coil supporter configured to support the magnetic field generating coil.

### CROSS-REFERENCE TO RELATED PATENT APPLICATION

This U.S. non-provisional patent application claims priority under 35 U.S.C. §119 of Japanese Patent Application Nos. 2009-114801, filed on May 11, 2009, and 2010-085197, filed on Apr. 1, 2010, in the Japanese Patent Office, the entire contents of which are hereby incorporated by reference.

### BACKGROUND OF THE INVENTION

1. Field of the Invention

The present invention relates to a vertical heat treatment apparatus and a heat treatment method for forming a silicon carbide (SiC) film on a substrate.

2. Description of the Prior Art

In a conventional silicon carbide (SiC) film forming apparatus, a plurality of substrates are disposed on a plane of a plate-shaped susceptor, and a film forming source gas is supplied to a reaction chamber from a single position.

Patent Document 1 discloses a vacuum film forming apparatus and a thin film forming method, in which a susceptor is disposed in a manner such that a substrate holding surface of the susceptor faces downward so as to solve problems, such as attachment of a deposit caused by a source gas to a surface facing the susceptor, and unstable epitaxial growth caused by a convection flow of a source gas.

[Patent document 1] Japanese Unexamined Patent Application Publication No. 2006-196807

However, according to the conventional art, since a large plate-shaped susceptor is necessary to process a plurality of substrates, a reaction chamber having a large floor area is necessary.

In addition, since silicon carbide (SiC) has a large energy band gap and dielectric strength voltage as compared with silicon (Si), silicon carbide attracts attention as an element material, particularly for an element of a power device. However, due to the characteristics of SiC such as a high melting point, a non-liquid state at normal pressure, and a low impurity diffusion coefficient, it is difficult, as is known, to fabricate a substrate or a device by using SiC as compared with the case of using Si. For example, since a SiC epitaxial film is formed in a high temperature range of about 1500° C. to about 1800° C. as compared with a temperature range of 900° C. to 1200° C. in which a Si epitaxial film is formed, it is necessary to study technology for heat-resistant structures of SiC epitaxial film forming apparatuses and source material decomposition preventing methods. In addition, since a film is grown as a result of reaction between two elements of silicon (Si) and carbon (C), additional studies which are not necessary for conventional silicon-based film forming apparatuses are required for ensuring a desired film thickness and a composition and controlling a doping level.

As SiC epitaxial film forming apparatuses for mass production, pancake type apparatuses and planetary type apparatuses are mainly sold in the market. In a film forming method, several SiC substrates to about ten SiC substrates are arranged on a plane of a susceptor which is heated to a film forming temperature, for example, by high-frequency waves, and a source gas and a carrier gas are supplied. Propane (C₃H₈) or ethylene (C₂H₄) is widely used as a carbon (C) source, monosilane (SiH₄) is widely used as a silicon (Si) source, and hydrogen (H₂) is widely used as a carrier gas. To control formation of silicon nuclei in a gaseous phase and improve crystalline quality, hydrogen chloride (HCl) may be added, or a material including chlorine (Cl) in its formula such as trichlorosilane (SiHCl₃) or tetrachlorosilane (SiCl₄, silicon tetrachloride) may be used as a source material. However, such SiC epitaxial film forming apparatuses may have the following problems.

Generally, in a reaction chamber structure of a conventional pancake or planetary type apparatus, a silicon source and a carbon source are supplied to wafers (substrates) disposed on a plane from a gas supply inlet installed at a center region, and the sources are exhausted through a peripheral exhaust outlet. Gas concentration distribution varies largely from the supply inlet to the exhaust outlet. Generally, to suppress film thickness non-uniformity caused by this, the wafers and a susceptor are rotated during a film forming process. To increase the number of substrates that can be processed at a time, a susceptor having a large diameter is preferable; however, in this case, the size of an apparatus and costs are increased. Such problems increase as the diameter of wafers increases.

In addition, if two or more wafers are arranged in a direction (radial direction) from the gas supply inlet to the gas exhaust outlet, due to the above-described gas concentration difference problem, film thicknesses of the wafers become different, and thus the number of wafers that can be practically processed at a time is limited.

In a vertical film forming apparatus used as a silicon film forming apparatus, a plurality of wafers (for example, twenty five to one hundred wafers) can be vertically arranged at a time in a footprint corresponding to a single wafer for, and the wafers can be batch-processed. Therefore, the vertical film forming apparatus is very suitable for mass production.

When such a vertical film forming apparatus is used for forming a SiC film, a problem of silicon source decomposition occurs. One of characteristics of a reaction chamber structure of such a vertical film forming apparatus may be the use of a gas introducing nozzle configured to uniformly supply a source gas to all substrates. Although varying according to the composition of a silicon source, the thermal decomposition temperature of monosilane (SiH₄) generally used as a silicon source is known to be about 800° C. or higher, and even silicon tetrachloride (SiCl₄) including chlorine is known to be thermally decomposed at about 1200° C. Generally, SiC is epitaxially grown at about 1500° C. to about 1800° C. In this case, the temperature of a nozzle disposed in a reaction chamber becomes equal to the inside temperature of the reaction chamber. Therefore, a silicon source gas is decomposed while the silicon source gas passes through the nozzle, and silicon extracted from the silicon source gas is deposited on the inner surface of the nozzle. Due to this, a source material may not be supplied to substrates, or the nozzle may be clogged by an extracted source. Thus, what is needed is to find a solution to extraction caused by thermal decomposition of a source in a nozzle.

### SUMMARY OF THE INVENTION

An object of the present invention is to provide a heat treatment apparatus configured to solve the following problems: when a silicon carbide (SiC) epitaxial film forming process is performed using a semiconductor manufacturing apparatus, since the inside of a reaction chamber in which a SiC film is epitaxially grown is kept in the temperature range from 1500° C. to 1800° C., the temperature of a gas supply nozzle is increased to a temperature higher than the decomposition temperature of a source gas, and thus the gas supply nozzle may be clogged due to deposition of extracted silicon on the inside of the gas supply nozzle or the source gas may be insufficiently supplied due to unnecessary consumption of the source gas caused by extraction of silicon.

According to an aspect of the present invention, there is provided a heat treatment apparatus comprising: a process chamber configured to grow silicon carbide (SiC) epitaxial films on SiC substrates; a substrate holding tool configured to hold a plurality of substrates in a state where the substrates are vertically arranged and approximately horizontally oriented, so as to hold the substrates in the process chamber; a first reaction gas supply nozzle configured to supply a carbon-containing gas into the process chamber; a second reaction gas supply nozzle configured to supply a silicon-containing gas into the process chamber; a magnetic field generating coil disposed at an outside of the process chamber for electromagnetic induction heating; and a coil supporter configured to support the magnetic field generating coil, wherein an upper end of the second reaction gas supply nozzle is lower than a lower end of the coil supporter configured to support the magnetic field generating coil.

### BRIEF DESCRIPTION OF THE DRAWINGS

FIG. 1 is a perspective view illustrating a heat treatment apparatus according to an embodiment of the present invention.

FIG. 2 is a side sectional view illustrating a process furnace used in an embodiment of the present invention.

FIG. 3 is a cross-sectional view illustrating the process furnace used in an embodiment of the present invention.

FIG. 4 is a schematic view illustrating the process furnace and the surrounding structures of the process furnace used in an embodiment of the present invention.

FIG. 5 is a block diagram illustrating a controller of the heat treatment apparatus according to an embodiment of the present invention.

FIG. 6 is a side sectional view illustrating a process furnace used in a second embodiment of the present invention.

FIG. 7 is a side sectional view illustrating a process furnace used in a third embodiment of the present invention.

### DETAILED DESCRIPTION OF THE PREFERRED EMBODIMENTS

### First Embodiment

Hereinafter, an embodiment of the present invention will be described with reference to the attached drawings.

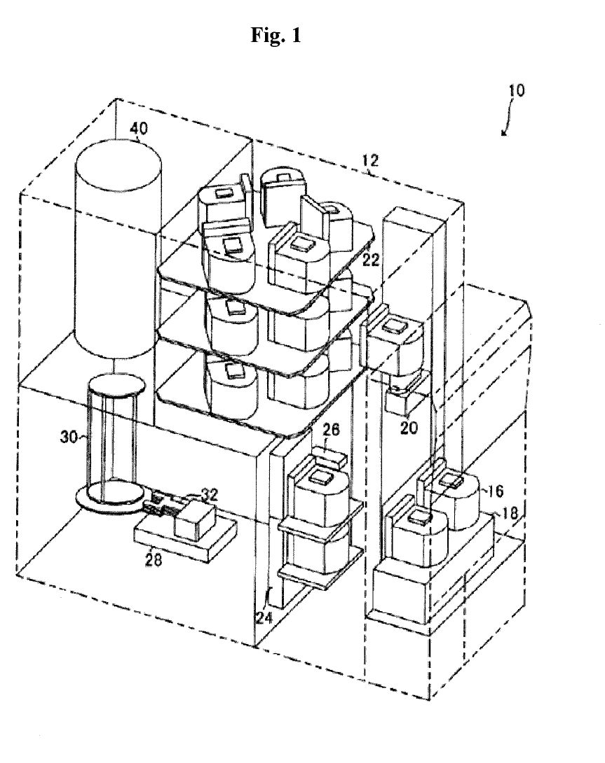

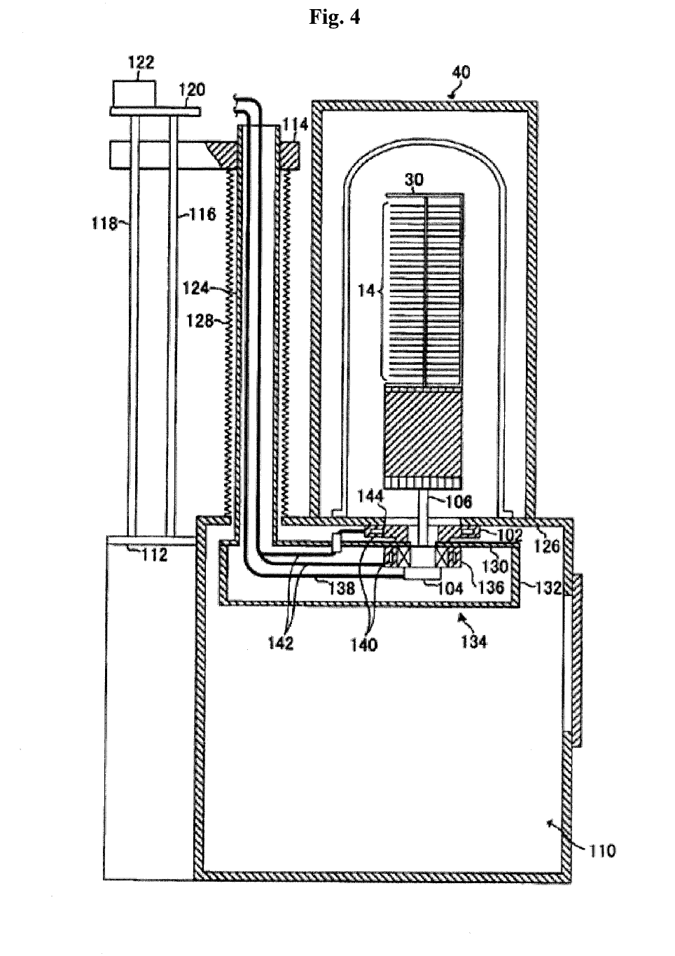

FIG. 1 is a perspective view illustrating a heat treatment apparatus 10 according to an embodiment of the present invention. The heat treatment apparatus 10 is a batch type vertical heat treatment apparatus and includes a case 12 in which main parts are disposed. In the heat treatment apparatus 10, FOUPs (Front Opening Unified Pods, hereinafter referred to as pods) 16, which are substrate containers configured to accommodate substrates such as wafers 14 (refer to FIG. 4) made of silicon, are used as wafer carriers. At the front side of the case 12, a pod stage 18 is disposed, and pods 16 are carried to the pod stage 18. For example, twenty five wafers 14 are accommodated in each pod 16, and the pod 16 is set on the pod stage 18 in a state where a cap of the pod 16 is closed.

At a front inner side of the case 12 opposite to the pod stage 18, a pod carrying device 20 is disposed. Furthermore, in the vicinity of the pod carrying device 20, a pod shelf 22, a pod opener 24, and a substrate counter 26 are disposed. The pod shelf 22 is disposed above the pod opener 24 and is configured such that a plurality of pods 16 can be placed and held on the pod shelf 22. The substrate counter 26 is disposed close to the pod opener 24. The pod carrying device 20 carries a pod 16 among the pod stage 18, the pod shelf 22, and the pod opener 24. The pod opener 24 is used to open a cap of a pod 16, and after the cap of the pod 16 is opened, the substrate counter 26 is used to count the number of wafers 14 disposed in the pod 16.

In the case 12, a substrate transfer machine 28, and a boat 30 which is a substrate holding tool are disposed. The substrate transfer machine 28 includes an arm (tweezers) 32 and is configured to be vertically moved and rotated by a driving unit (not shown). The arm 32 can pick up wafers 14 (for example, five wafers 14), and by operating the arm 32, wafers 14 can be carried between a pod 16 placed at the pod opener 24 and the boat 30.

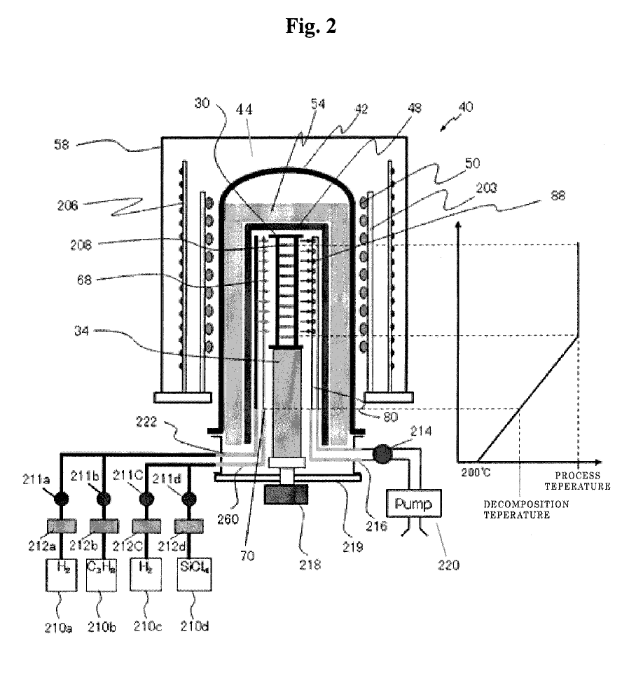

The boat 30 is made of a heat-resistant material such as carbon graphite or silicon carbide and is configured to hold a plurality of wafers 14 in a manner such that the wafers 14 are horizontally oriented and vertically arranged in multiple stages with the centers of the wafers 14 being aligned with each other. In addition, at the lower part of the boat 30, a boat insulating part 34 is disposed as a circular disk shaped insulating member made of a heat-resistant material such as quartz or silicon carbide, so as to prevent heat transfer from a heating target object (susceptor) 48 (described later) to the lower side of a process furnace 40 (refer to FIG. 2).

At the rear upper part in the case 12, the process furnace 40 is disposed. In the process furnace 40, the boat 30 charged with a plurality of wafers 14 is loaded, and a heat treatment is performed.

Next, the process furnace 40 will be described.

FIG. 2 is a schematic view illustrating a heat treatment apparatus used in a first embodiment.

The current embodiment is configured by a reaction tube 42 which forms a reaction space and is mainly made of quartz; an induction coil (magnetic coil) 50 configured to heat wafers to a process temperature; support posts 203 configured to support the induction coil 50 and made of an insulating material (for example, a ceramic material such as alumina); and a heating target object (susceptor) 48 configured to be heated by an eddy current generated by the induction coil 50 and made of carbon graphite coated with SiC. The heating target object 48 is configured to be heated by a magnetic field generated by the induction coil 50 installed outside the reaction tube 42. As the heating target object 48 is heated, the inside of the reaction tube 42 is heated.

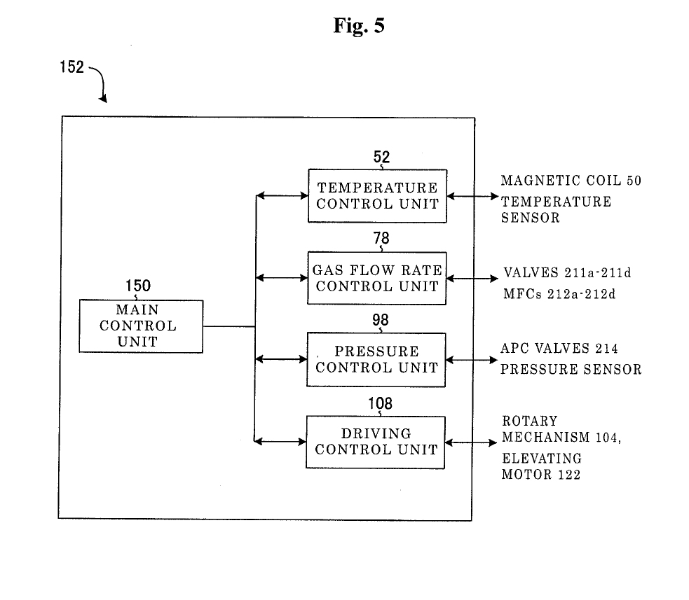

Near the heating target object 48, a temperature sensor (not shown) is installed as a temperature detector configured to detect the inside temperature of a process chamber 44. The induction coil 50 and the temperature sensor are electrically connected to a temperature control unit 52, and the temperature control unit 52 is configured to adjust power to the induction coil 50 based on temperature information detected by the temperature sensor so as to obtain desired temperature distribution in the process chamber 44 at a desired time (refer to FIG. 5).

The current embodiment is also configured by a thermal insulator 54 mainly made of a carbon fiber (carbon felt) so as to prevent the temperature of a reaction tube wall from being increased by radiant heat from the heating target object 48 heated to a process temperature; a cooling plate 206 which is a cooling part; a case cover 58 configured to prevent leakage of electromagnetic waves and heat to an outside area; wafer holders 208 which are substrate holding parts made of carbon graphite coated with SiC so as to prevent formation of films on the backsides of wafers; a boat 30 made of carbon graphite coated with SiC and configured to hold the wafer holders 208 in a state where the wafer holders 208 are stacked and wafers are set on the wafer holders 208; a gas supply nozzle 260 connected to source tanks 210a to 210d which are gas supply parts configured to supply source gases to wafers through valves 211a to 211d and flow rate control devices (mass flow controllers, MFCs) 212a to 212d; an exhaust nozzle upper part 80 which is an exhaust system connected to a pump 220 through a pressure control valve 214 functioning as a pressure controller to form uniform gas flows between wafers; an exhaust nozzle lower part 216; a lower insulating part 34 configured to prevent heating of a seal member disposed at a lower side of a reaction chamber; a rotation shaft 218 which is a rotary device configured to rotate wafers during a processing process for forming films having a uniform thickness on the wafers; and a seal part 219 connected to a vertical actuating unit (not shown) configured to load stacked wafers into the reaction chamber and unload from the reaction chamber, so as to hermetically close an opening formed in the bottom side of the reaction chamber.

Operations will now be explained. The boat 30, fixed to the seal part 219 and in which the wafer holders 208 are mounted in a state where wafers are set on the wafer holders 208, is loaded into the reaction chamber by using the vertical actuating unit (not shown), and the reaction chamber is hermetically closed. While introducing inert gas (for example, Ar) into a furnace, the inside pressure of the reaction chamber is kept at a desired level by using the pump 220 connected to the reaction chamber through the pressure control valve 214. High-frequency power (for example, 10 KHz to 100 KHz, 10 KW to 200 KW) is supplied to the induction coil 50 to generate eddy currents in the heating target object 48 for heating the heating target object 48 to a desired process temperature (1500° C. to 1800° C.) by joule heat. Therefore, the wafers, the wafer holders 208, and the boat 30 that are disposed inside the heating target object 48 can be heated by radiant heat from the heating target object 48 to a temperature corresponding to the temperature of the heating target object 48.

The periphery of the bottom-side opening of the reaction chamber is kept at a low temperature (of about 200° C.) by the heat resistance of the seal member (such as an O-ring) and a lower insulating member. A silicon-based source (such as SiCl₄ showing in the drawing, SiH₄, TCS: trichlorosilane, or DCS: dichlorosilane) mixed with a carrier gas is supplied through the gas supply nozzle 260 to the wafers kept at a process temperature (1500° C. to 1800° C.), and a carbon-based source (such as C₃H₈ shown in the drawing or C₂H₄) is supplied to the wafers through a source gas supply nozzle upper part 68 and a source gas supply nozzle lower part 222. Along with this, while adjusting the inside pressure of the reaction tube 42 to a desired pressure by using the pressure control valve 214, a SiC epitaxial film forming process is performed.

During the film forming process, the wafers are rotated by the rotation shaft 218 for ensuring the in-surface film uniformity of the wafers. Here, as described above, in a temperature range of 1500° C. to 1800° C., the silicon-based source (gas) decomposes, and silicon is extracted from the silicon-based source gas. However, in the present invention, to prevent decomposition of the silicon-based source gas in the gas supply nozzle 260 and the resulting extraction of silicon, a nozzle opening (nozzle upper end) 70 is formed in a region kept at a temperature lower than the decomposition temperature of the silicon-based source gas, and the silicon-based source gas is supplied by ejecting the silicon-based source gas toward a wafer disposition region. Therefore, gas inside the gas supply nozzle 260 is not heated to a temperature higher than its decomposition temperature, thereby preventing extraction of silicon. This prevents problems such as the case where a silicon-based source gas is not supplied to substrates due to deposition of the silicon-based source gas on the inner surface of the gas supply nozzle 260 or the case where the gas supply nozzle 260 is clogged by extraction of a silicon-based source.

Exhaust holes 88 are formed in the exhaust nozzle upper part 80 at heights corresponding to gaps between the wafers so that gas passing between the wafers can be rectified. Since a carbon-based source gas is not deposited although it is heated to a temperature of 1500° C. to 1800° C., it is configured such that the carbon-based source gas is ejected through lateral holes of the source gas supply nozzle upper part 68 corresponding to the gaps between the wafers for uniformly supplying the carbon-based source gas to the wafers, and owing to this configuration, the exhaust nozzle upper part 80, and the exhaust nozzle lower part 216, rectification of gas flowing between the wafers can be facilitated. In addition, the source gas supply nozzle upper part 68, the source gas supply nozzle lower part 222, the exhaust nozzle upper part 80, and the exhaust nozzle lower part 216 are constructed by combining quartz and carbon graphite: nozzle lower sides which are maximally heated to about 1000° C. or lower are made of quartz; and the other nozzle upper sides are made of carbon graphite which is surface-treated for hydrogen resistance (for example, SiC coating).

In the exhaust nozzle upper part 80, the exhaust holes 88 are formed to exhaust gas from the respective wafers held by the boat 30. The exhaust holes 88 may be provided in a manner such that one exhaust hole 88 is provided for a wafer or several wafers.

Owing to this structure, gas ejected through the lateral holes of the source gas supply nozzle upper part 68 flows toward the exhaust holes 88. Therefore, the gas can flow in parallel with the wafers, and the entire areas of the wafers can be efficiently and uniformly exposed to the gas.

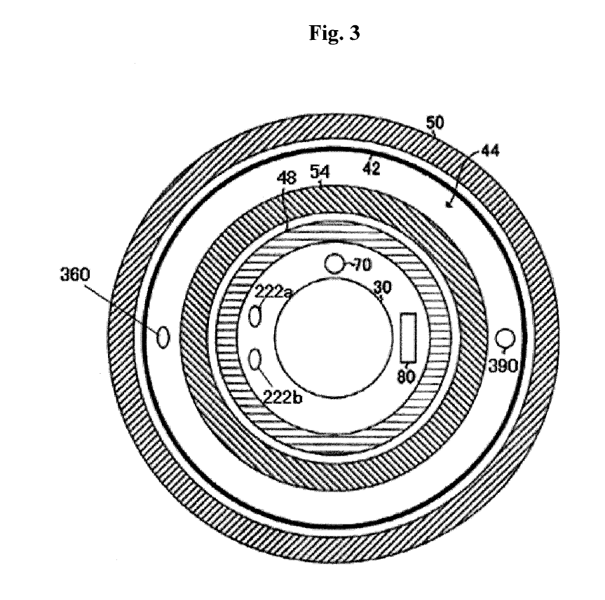

The gas supply nozzle 260, the nozzle opening (gas supply nozzle) 70, and the exhaust nozzle upper part (gas exhaust nozzle) 80 will now be described in detail. Referring to FIG. 3, three gas supply nozzles 222a, 222b, and 70 are disposed in the susceptor 48, and a gas supply nozzle 360 is disposed between the reaction tube 42 and the thermal insulator 54. A carbon-containing gas (for example, C₃H₈ or C₂H₄) diluted with H₂ or inert gas such as Ar is introduced through the gas supply nozzles 222a and 222b, a silicon-containing gas (for example, SiCl₄, SiH₄, TCS, or DCS) is introduced through the gas supply nozzle 70. Gases that can be introduced through the gas supply nozzles 222a, 222b, and 70 are not limited to the above-mentioned gases. That is, other proper gases may be used according to purposes. A plurality of carbon-containing gas supply nozzles may be provided, and a plurality of silicon (Si)-containing gas supply nozzles may be provided. Hereinafter, such gases used for processing (forming films on) wafers disposed in the process chamber 44 will be referred to as reaction gases.

Between the reaction tube 42 and the thermal insulator 54, the gas supply nozzle 360 is disposed to introduce inert gas such as argon gas. The gas supply nozzle 360 is provided to prevent permeation of a reaction gas between the reaction tube 42 and the thermal insulator 54, and thus to prevent unnecessary attachment of a product to the inner wall of the reaction tube 42 and prevent deteriation of an insulating material caused by hydrogen.

At the inside of the susceptor 48, the nozzle opening 70 is disposed. A dopant gas such as nitrogen (N₂), trimethylaluminium (TMA), diborane (B₂H₆), or boron trichloride (BCl₃) is introduced through the nozzle opening 70.

The present invention is characterized by the gas supply nozzle 260. As described above, in a temperature range of 1500° C. to 1800° C., a silicon-containing source gas decomposes, and silicon is extracted. Therefore, to prevent decomposition of a silicon-containing source gas in a nozzle and the resulting extraction of silicon, the nozzle opening 70 which is an upper end of a gas supply nozzle is formed in a region kept at a temperature lower than the decomposition temperature of the silicon-containing source gas, for example, at a position not higher than the lower insulating part (boat insulating part) 34, and the silicon-containing source gas is supplied by ejecting the silicon-containing source gas toward a wafer disposition region. Therefore, the temperature of the gas in the nozzle is not increased to or above the decomposition temperature of the gas, thereby preventing extraction of silicon. This prevents problems such as the case where a source gas is not supplied to substrates due to deposition of the source gas on the inner surface of a nozzle or the case where the nozzle is clogged by extraction of the source gas. If the silicon-containing source gas is supplied from a too low position, the silicon-containing source gas may not be efficiently consumed due to the large distance between the low position and wafers 14. Therefore, it may be ideal that the silicon-containing source gas be supplied from a position lower than the wafers 14 and kept at a temperature lower than the decomposition temperature of the silicon-containing source gas. In addition, if a gas having a low decomposition temperature is used, the gas supply nozzle 260 may be formed into a double pipe structure constituted by an inner pipe and an outer pipe, and a cooling medium may be supplied between the inner pipe and the outer pipe.

The exhaust holes 88 corresponding to gaps between wafers are in the exhaust nozzle 80 so that gas passing between the wafers can be rectified. Since a carbon-based source gas is not deposited although it is heated to a temperature of 1500° C. to 1800° C., it is configured such that the carbon-based source gas is ejected through the lateral holes of the source gas supply nozzle upper part 68 corresponding to the gaps between the wafers for uniformly supplying the carbon-based source gas to the wafers, and owing to this configuration and the exhaust nozzle 80, rectification of gas flowing between the wafers can be facilitated. In addition, as described above, the source gas supply nozzles and the exhaust nozzle are constructed by combining quartz and carbon graphite: parts which are maximally heated to about 1000° C. or lower are made of quartz; and the parts are made of carbon graphite which is surface-treated for hydrogen resistance (for example, SiC coating).

Furthermore, in the susceptor 48, the gas exhaust nozzle 80 is disposed at a side opposite to the gas supply nozzles 222a and 222b. The gas exhaust nozzle 80 is configured to exhaust reaction gases mainly.

At a side opposite to the gas supply nozzle 360 between the reaction tube 42 and the thermal insulator 54, a gas exhaust outlet 390 is disposed. The gas exhaust outlet 390 is configured to mainly exhaust gas, which is introduced through the gas supply nozzle 360 to purge an insulator region.

In the above-described structure of the process furnace 40, gases are introduced into the reaction tube 42 from the gas supply nozzles 222a and 222b and the nozzle opening 70 as follows: gases are supplied from gas supply sources (not shown) to corresponding gas supply pipes, and after the flow rates of the gases are adjusted at MFCs 212a to 212d, the gases are introduced into the reaction tube 42 through valves 211a to 211d.

Then, the gases introduced into the reaction tube 42 are exhausted from the reaction tube 42 by the pump 220 (vacuum exhaust device) connected to gas exhaust pipes corresponding to the gas exhaust nozzle 80 and the gas exhaust outlet 390.

Next, the surrounding structures of the process furnace 40 will be described.

FIG. 4 is a schematic view illustrating the process furnace 40 and the surrounding structures of the process furnace 40. At the bottom side of the process furnace 40, a seal cap 102 is installed as a furnace port cover to hermetically close the bottom-side opening of the process furnace 40. For example, the seal cap 102 is made of a metal such as stainless steel and has a circular disk shape. On the top surface of the seal cap 102, an O-ring is installed as a seal member configured to make contact with the bottom side of the process furnace 40.

At the seal cap 102, a rotary mechanism 104 is installed. A rotation shaft 106 of the rotary mechanism 104 is connected to the boat 30 through the seal cap 102 and is configured to rotate wafers 14 by rotating the boat 30. The seal cap 102 is configured to be vertically lifted and lowered by an elevating motor 122 (described later) installed at the outside of the process furnace 40 as an elevating mechanism, so as to load the boat 30 into the process furnace 40 and unload the boat 30 from the process furnace 40. The rotary mechanism 104 and the elevating motor 122 are electrically connected to a driving control unit 108, and thus desired operations can be performed at desired times under the control of the driving control unit 108 (refer to FIG. 5).

At the outer surface of a loadlock chamber 110 which is a preliminary chamber, a lower base plate 112 is installed. A guide shaft 116 fitted in an elevating table 114, and a ball screw 118 screw-coupled with the elevating table 114 are installed at the lower base plate 112. On the upper ends of the guide shaft 116 and the ball screw 118 erected on the lower base plate 112, an upper base plate 120 is installed. The ball screw 118 is rotated by the elevating motor 122 installed on the upper base plate 120. As the ball screw 118 is rotated, the elevating table 114 is lifted or lowered.

At the elevating table 114, a hollow elevating shaft 124 is installed to be extended from the elevating table 114, and a joint part between the elevating table 114 and the elevating shaft 124 is hermetically kept. The elevating shaft 124 and the elevating table 114 are configured to be lifted and lower together with each other. The elevating shaft 124 is movably inserted through a top plate 126 of the loadlock chamber 110. A penetration hole of the top plate 126 through which the elevating shaft 124 is movably inserted is sufficiently large so that the elevating shaft 124 does not make contact with the top plate 126 at the penetration hole. Between the loadlock chamber 110 and the elevating table 114, a bellows 128 is installed as a hollow flexible part configured to enclose the elevating shaft 124, so that the loadlock chamber 110 can be hermetically kept. The bellows 128 can be sufficiently expanded and contracted in accordance with lifting motions of the elevating table 114, and the bellows 128 has an inner diameter sufficiently greater than the outer diameter of the elevating shaft 124 so as not to make contact with the elevating shaft 124 during expansion or contraction.

An elevating base plate 130 is horizontally fixed to the lower end of the elevating shaft 124. A driving unit cover 132 is hermetically attached to the bottom surface of the elevating base plate 130 with a seal member such as an O-ring being disposed therebetween. The elevating base plate 130 and the driving unit cover 132 constitute a driving unit accommodation case 134. In this way, the inside of the driving unit accommodation case 134 is isolated from the inside atmosphere of the loadlock chamber 110.

In addition, the rotary mechanism 104 for the boat 30 is installed in the driving unit accommodation case 134, and the periphery of the rotary mechanism 104 is cooled by a cooling mechanism 136.

A power supply cable 138 extends from the upper end of the elevating shaft 124 to the rotary mechanism 104 through the hollow part of the elevating shaft 124, and then the power supply cable 138 is connected to the rotary mechanism 104. In addition, cooling channels 140 are formed in the cooling mechanism 136 and the seal cap 102. Coolant conduits 142 extend from the upper end of the elevating shaft 124 to the cooling channels 140 through the hollow part of the elevating shaft 124, and then the coolant conduits 142 are connected to the cooling channels 140.

By rotating the ball screw 118 using the elevating motor 122, the driving unit accommodation case 134 can be lifted or lowered through the elevating table 114 and the elevating shaft 124.

If the driving unit accommodation case 134 is lifted, a furnace port 144 which is an opening of the process furnace 40 is closed by the seal cap 102 hermetically installed at the elevating base plate 130, and thus it becomes a wafer processible state. If the driving unit accommodation case 134 is lowered, the boat 30 is also lowered together with the seal cap 102, and in this state, wafers 14 can be carried to an outside area.

FIG. 5 illustrates a configuration for controlling each part of the heat treatment apparatus 10.

The temperature control unit 52, the gas flow rate control unit 78, the pressure control unit 98, and the driving control unit 108 constitute a manipulation unit and an input/output unit and are electrically connected to a main control unit 150 that controls the overall operation of the heat treatment apparatus 10. The temperature control unit 52, the gas flow rate control unit 78, the pressure control unit 98, and the driving control unit 108 are configured as a controller 152.

Next, an explanation will be given on a method of forming a film such as SiC (silicon carbide) film on a substrate such as a SiC wafer 14 by using the above-described heat treatment apparatus 10 in one of semiconductor device manufacturing processes. In the following explanation, each part of the heat treatment apparatus 10 is controlled by the controller 152.

First, if a pod 16 accommodating a plurality of wafers 14 is set on the pod stage 18, the pod carrying device 20 carries the pod 16 from the pod stage 18 to the pod shelf 22 so that the pod shelf 22 is stocked with the pod 16. Next, the pod carrying device 20 carries the pod 16 from the pod shelf 22 to the pod opener 24 and set the pod 16 on the pod opener 24; the pod opener 24 opens a cap of the pod 16; and the substrate counter 26 detects the number of the wafers 14 accommodated in the pod 16.

Next, the substrate transfer machine 28 picks up wafers 14 from the pod 16 placed on the pod opener 24 and transfers the wafers 14 to the boat 30.

After a plurality of wafers 14 are charged into the boat 30, the boat 30 charged with the wafers 14 is loaded into the process chamber 44 (boat loading) as the elevating table 114 and the elevating shaft 124 are lifted by the elevating motor 122. At this time, the bottom side of the top plate 126 is sealed by the seal cap 102 in a state where the O-ring being disposed between the top plate 126 and the seal cap 102.

The inside of the process chamber 44 is vacuum-evacuated by the vacuum exhaust device 220 to a predetermined pressure (vacuum degree). At this time, the inside pressure of the reaction tube 42 is measured using a pressure sensor, and based on the measured pressure, automatic pressure controller (APC) valves corresponding to the gas exhaust nozzle 80 and the gas exhaust outlet 390 are feedback-controlled. In addition, the inside of the reaction tube 42 is heated by the susceptor 48 to a predetermined temperature. At this time, to obtain desired temperature distribution in the reaction tube 42, power to the magnetic coil 50 is feedback-controlled based on temperature information detected by a temperature sensor. Subsequently, the rotary mechanism 104 rotates the boat 30 to rotates the wafers 14 charged in the boat 30.

Subsequently, carbon-containing gases (reaction gases) are supplied to the gas supply nozzles 222a and 222b from process gas supply sources (not shown), respectively. To keep the flow rates of the reaction gases at desired levels, after controlling the opened degrees of the MFCs 212a and 212b corresponding to the gas supply nozzles 222a and 222b, the valves 211a and 211b are opened. Then, the respective reaction gases flow through the gas supply nozzles 222a and 222b and are introduced into the reaction tube 42 through gas supply holes of the gas supply nozzles 222a and 222b. In addition, after controlling the opened degree of the MFCs 212c and 212d, the valves 211c and 211d are opened. Then, a silicon-containing gas flows through the gas supply nozzle 260 and is introduced into the reaction tube 42 through the nozzle opening 70. The gases introduced through the gas supply nozzles 222a and 222b and the nozzle opening 70 are allowed to flow through the inside of the susceptor 48 disposed in the reaction tube 42 and are exhausted mainly from the gas exhaust nozzle 80 through the exhaust nozzle lower part 216. When the reaction gases flow through the inside of the reaction tube 42, the reaction gases make contact with the wafers 14 so that SiC films can be deposited on the surfaces of the wafers 14.

In addition, gas is supplied to the gas supply nozzle 360 from a gas supply source (not shown). To keep the flow rate of the gas at a desired level, after controlling the opened degree of an MFC corresponding to the gas supply nozzle 360, a valve is opened. Then, the gas flows through a gas supply pipe and is introduced into the reaction tube 42 through supply holes. The gas introduced through the gas supply nozzle 360 flows between the inside of the reaction tube 42 and the outside of the thermal insulator 54 is mainly exhausted from the gas exhaust outlet 390.

After a predetermined time, inert gas is supplied from an inert gas supply source (not shown) to replace the inside atmosphere of the reaction tube 42 with the inert gas, and along with this, the inside pressure of the reaction tube 42 is returned to normal pressure.

Thereafter, the seal cap 102 is lowered by the elevating motor 122 to open the bottom side of the top plate 126, and along with this, the processes wafers 14 are unloaded from the reaction tube 42 through the bottom side of the top plate 126 in a state where the processed wafers 14 are held in the boat 30 (boat unloading), and the boat 30 is left at a predetermined position until all the wafers 14 held in the boat 30 are cooled. Next, if the wafers 14 of the boat 30 are cooled to a predetermined temperature, the substrate transfer machine 28 picks up the wafers 14 from the boat 30 and carries the wafers 14 into an empty pod 16 set on the pod opener 24. Thereafter, the pod carrying device 20 carries the pod 16 in which the wafers 14 are accommodated to the pod shelf 22 or the pod stage 18. In this way, a series of operations of the heat treatment apparatus 10 is completed.

### Second Embodiment

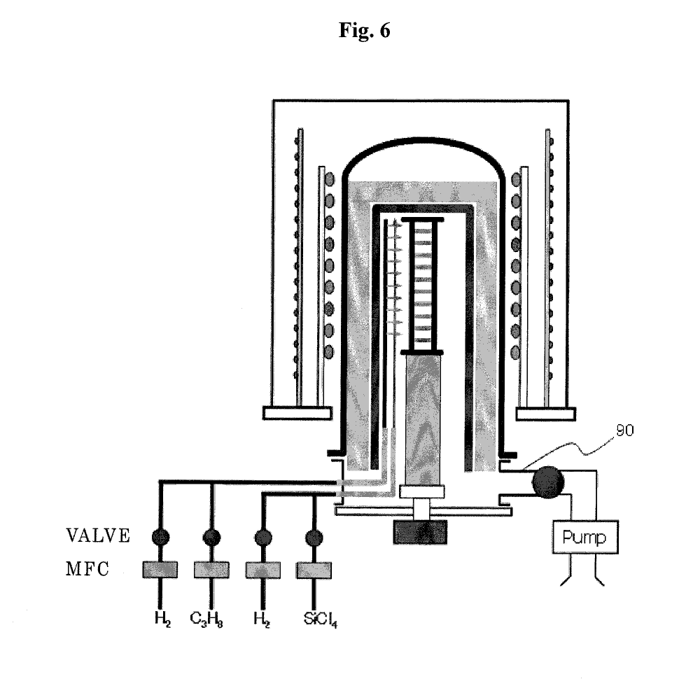

Next, a second embodiment will be described. FIG. 6 is a schematic view illustrating a heat treatment apparatus used in the second embodiment. In this modification example, at a gas exhaust side, an exhaust nozzle lower part is disposed but an exhaust nozzle upper part is not disposed. The other structure is the same as that in the first embodiment.

### Third Embodiment

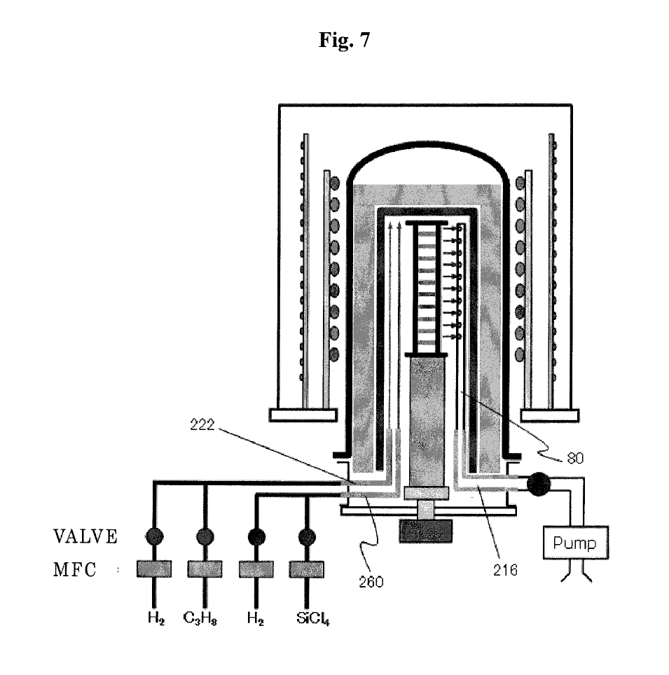

Next, a third embodiment will be described. FIG. 7 is a schematic view illustrating a heat treatment apparatus used in the third embodiment. In this modification example, the lower parts of a silicon-containing gas supply nozzle 222 and a carbon-containing gas supply nozzle 260 are disposed in a manner such that the upper ends of the nozzles 222 and 260 are disposed at a lower side of a reaction chamber which is kept at a temperature lower than the thermal decomposition temperature of silicon. In addition, at a gas exhaust side, an exhaust nozzle upper part 80 and an exhaust nozzle lower part 216 are disposed. The other structure is the same as that in the first embodiment.

The present invention is not limited to the above-described embodiments. For example, the number, arrangement or combination of the gas supply nozzle 260, the nozzle opening 70, the gas exhaust nozzle 80, and the gas exhaust outlet 390 may be properly changed according to purposes.

As described above, the heat treatment apparatus of the present invention makes it possible to solve problems such as clogging of the gas supply nozzle caused by extraction of silicon in the gas supply nozzle and insufficient supply of a source gas to a substrate caused by unnecessary consumption of the source gas resulted from extraction of silicon from the source gas.

(Supplementary Note) The present invention also includes the following embodiments.

Supplementary Note 1)

According to an embodiment of the present invention, there is provided a heat treatment apparatus comprising: a process chamber configured to grow silicon carbide (SiC) epitaxial films on SiC substrates; a substrate holding tool configured to hold a plurality of substrates in a state where the substrates are vertically arranged and approximately horizontally oriented, so as to hold the substrates in the process chamber; a first reaction gas supply nozzle configured to supply a carbon-containing gas into the process chamber; a second reaction gas supply nozzle configured to supply a silicon-containing gas into the process chamber; a magnetic field generating coil disposed at an outside of the process chamber for electromagnetic induction heating; and a coil supporter configured to support the magnetic field generating coil, wherein an upper end of the second reaction gas supply nozzle is lower than a lower end of the coil supporter configured to support the magnetic field generating coil.

(Supplementary Note 2)

The heat treatment apparatus of Supplementary Note 1 may further comprise an exhaust nozzle in which a plurality of exhaust holes are formed at positions corresponding to gaps between the substrates, respectively.

(Supplementary Note 3)

In the heat treatment apparatus of Supplementary Note 1, the silicon-containing gas may be supplied by ejecting the silicon-containing gas upward from a position lower than a region in which the substrates are arranged, and the carbon-containing gas may be supplied through holes of the first reaction gas supply nozzle which are formed at positions corresponding to gaps between the substrates.

(Supplementary Note 4)

According to another embodiment of the present invention, there is provided a heat treatment apparatus comprising: a process chamber configured to grow SiC epitaxial films on SiC substrates; a substrate holding tool configured to hold a plurality of substrates in a state where the substrates are vertically arranged and approximately horizontally oriented, so as to hold the substrates in the process chamber; a first reaction gas supply nozzle configured to supply a carbon-containing gas into the process chamber; a second reaction gas supply nozzle configured to supply a silicon-containing gas into the process chamber; a magnetic field generating coil disposed at an outside of the process chamber for electromagnetic induction heating; and a coil supporter configured to support the magnetic field generating coil, wherein an upper end of the second reaction gas supply nozzle is disposed at a position which is lower than the lowermost substrate of the vertically arranged substrates and is kept at a temperature lower than a decomposition temperature of the silicon-containing gas.

(Supplementary Note 5)

In the heat treatment apparatus of Supplementary Note 1 or 4, a lower part of the first reaction gas supply may be made of quartz.

What is claimed is:

1. A heat treatment apparatus comprising:
a process chamber configured to grow silicon carbide (SiC) epitaxial films on SiC substrates;
a substrate holding tool configured to hold a plurality of substrates in a state where the substrates are vertically arranged and approximately horizontally oriented, so as to hold the substrates in the process chamber;
a first reaction gas supply nozzle configured to supply a carbon-containing gas into the process chamber;
a second reaction gas supply nozzle configured to supply a silicon-containing gas into the process chamber;
a magnetic field generating coil disposed at an outside of the process chamber for electromagnetic induction heating; and
a coil supporter configured to support the magnetic field generating coil,
wherein an upper end of the second reaction gas supply nozzle is lower than a lower end of the coil supporter configured to support the magnetic field generating coil.

2. The heat treatment apparatus of claim 1, further comprising an exhaust nozzle in which a plurality of exhaust holes are formed at positions corresponding to gaps between the substrates, respectively.

3. The heat treatment apparatus of claim 1, wherein the silicon-containing gas is supplied by ejecting the silicon-containing gas upward from a position lower than a region in which the substrates are arranged, and the carbon-containing gas is supplied through holes of the first reaction gas supply nozzle which are formed at positions corresponding to gaps between the substrates.

4. A heat treatment apparatus comprising:
a process chamber configured to grow SiC epitaxial films on SiC substrates;
a substrate holding tool configured to hold a plurality of substrates in a state where the substrates are vertically arranged and approximately horizontally oriented, so as to hold the substrates in the process chamber;
a first reaction gas supply nozzle configured to supply a carbon-containing gas into the process chamber;
a second reaction gas supply nozzle configured to supply a silicon-containing gas into the process chamber;
a magnetic field generating coil disposed at an outside of the process chamber for electromagnetic induction heating; and
a coil supporter configured to support the magnetic field generating coil,
wherein an upper end of the second reaction gas supply nozzle is disposed at a position which is lower than the lowermost substrate of the vertically arranged substrates and is kept at a temperature lower than a decomposition temperature of the silicon-containing gas.

5. The heat treatment apparatus of claim 1, wherein a lower part of the first reaction gas supply nozzle is made of quartz.

6. The heat treatment apparatus of claim 4, wherein a lower part of the first reaction gas supply nozzle is made of quartz.
